(19) United States
(12) Patent Application Publication
(10) Pub. No.: US 2018/0124952 A1
(43) Pub. Date: May 3, 2018

(54) MODULAR DEWAR SYSTEM

(71) Applicants: Fouad E. Kiamilev, Hockessin, DE (US); Andrea Waite, Newark, DE (US)

(72) Inventors: Fouad E. Kiamilev, Hockessin, DE (US); Andrea Waite, Newark, DE (US)

(73) Assignee: UNIVERSITY OF DELAWARE, NEWARK, DE (US)

(21) Appl. No.: 15/795,667

(22) Filed: Oct. 27, 2017

Related U.S. Application Data
(60) Provisional application No. 62/416,253, filed on Nov. 2, 2016.

(51) Int. Cl. H05K 7/20; H05K 1/18; H05K 5/06; H05K 7/14

(52) U.S. Cl. CPC H05K 7/20354; H05K 1/18; H05K 2201/10106; H05K 7/1427; H05K 5/069

(57) ABSTRACT

An embodiment includes a modular dewar comprising a vacuum chamber, and a dewar circuit board. The dewar circuit board includes an inner portion including an electronic device positioned inside the vacuum chamber, an outer portion including electrical connectors positioned outside the vacuum chamber, and electrical traces connecting the electronic device inside the vacuum chamber to the electrical connectors outside the vacuum chamber.

### CROSS REFERENCE TO RELATED APPLICATIONS

This application claims priority to U.S. Provisional Application No. 62/416,253, filed Nov. 2, 2016. The contents of U.S. Provisional Application No. 62/416,253 are incorporated by reference herein.

### FIELD

The present invention relates to a modular dewar system for controlling the temperature of electronic components.

### BACKGROUND

Some electronic components generate a large amount of heat that must be extracted before they fail. One such example is an infrared light emitting diode (IRLED) projector having an IRLED array and supporting electronics. Conventional solutions for cooling the IRLED projector include enclosing the IRLED array in vacuum sealed dewar. Refrigerant is pumped into a heat exchanger to cool the IRLED array.

These conventional solutions, however, are problematic due to the electrical connections to the IRLED array. Due to the IRLED array being enclosed in the dewar, the electrical connections and corresponding wires are also enclosed in the dewar. This requires that the electrical wires be routed from the IRLED array through the dewar to dedicated electrical connections penetrating the dewar that allow the internal wires to be electrically connected to external electronic devices (e.g. IRLED controller). Once the wires are routed through the dewar and the connected to the dedicated electrical connections, this electrical configuration is fixed and cannot be easily altered. Therefore, the conventional dewar system is not easily reconfigured to support different electronic devices that need to be cooled (e.g. another LED array with different electrical requirements).

### SUMMARY

An embodiment includes a modular dewar comprising a vacuum chamber, and a dewar circuit board. The dewar circuit board includes an inner portion including an electronic device positioned inside the vacuum chamber, an outer portion including electrical connectors positioned outside the vacuum chamber, and electrical traces connecting the electronic device inside the vacuum chamber to the electrical connectors outside the vacuum chamber.

Another embodiment includes a circuit board for cryo-packaging. The circuit board comprising an inner portion including an electronic device, the inner portion having a first predetermined geometry for positioning inside a vacuum chamber, an outer portion including electrical connectors, the outer portion having a second predetermined geometry for positioning outside the vacuum chamber with the inner portion positioned inside a vacuum chamber, and electrical traces connecting the electronic device to the electrical connectors.

Yet another embodiment includes a modular dewar comprising a vacuum chamber defined by a front lid and a rear lid, an interposer comprising an electrically insulating substrate having a first face in contact with a first vacuum seal in contact with the front lid and a second face in contact with a second vacuum seal in contact with the rear lid. The interposer comprising an inner portion positioned inside the vacuum chamber and containing a first electronic component, an outer portion positioned outside the vacuum chamber and containing one or more second electronic components, and electrically conductive layers or members, and a temperature regulation device configured to cool the dewar, wherein the modular dewar is configured to permit exchanging the first electronic component for a second electronic component different than the first electronic component without requiring modifications to the modular dewar.

### BRIEF DESCRIPTION OF THE FIGURES

FIG. 1 is a view of an array of IRLEDs for projecting a pixelated image, according to an embodiment of the present invention.

FIG. 2 is a view of a system including the array of IRLEDs cryo-packaged in the modular dewar system, according to an embodiment of the present invention.

FIG. 3A is a side view of the modular dewar system in FIG. 2, according to an embodiment of the present invention.

FIG. 3B is an exploded view of the modular dewar system in FIG. 3A, according to an embodiment of the present invention.

FIG. 3C is a zoomed-in view of the head of the modular dewar system in FIG. 3A, according to an embodiment of the present invention.

FIG. 3D is side view of the IRLED array mounted to an interposer board for installation in the modular dewar system in FIG. 3A, according to an embodiment of the present invention.

FIG. 4A is a perspective view of another system including an array of IRLEDs cryo-packaged in the modular dewar system, according to an embodiment of the present invention.

FIG. 4B is an exploded view of the modular dewar system in FIG. 4A, according to an embodiment of the present invention.

FIG. 5 is flowchart of assembling and operating the modular dewar system, according to an embodiment of the present invention.

### DETAILED DESCRIPTION

Some electrical components may benefit from or require isolation from the ambient environment for various reasons (e.g. they may benefit from a temperature controlled environment). Vacuum sealing these components in a modular dewar is a solution to achieve this isolation.

Aspects of the present invention provides a method and system for vacuum sealing electronic components in a modular dewar to isolate these components from the ambient environment, while allowing convenient access to electrical connections if the components. Electrical components that may benefit from or require vacuum sealing include but are not limited to emitter/detector systems and superconductor integrated circuits (ICs) that require cooling for achieving low operating temperatures, infrared light emitting diodes (IRLEDs) that require temperature regulation, IC chips that require temperature range testing, or components that may not require cooling/heating, but may require isolation from the ambient environment.

An embodiment of the present invention provides a method and system for extracting heat from electronic components. The method and system utilizes a cryo-packaging device including a modular dewar system having a circuit board sized to be installed such that the electronic device is inside the modular dewar and the electrical connections to the electronic device are outside the modular dewar.

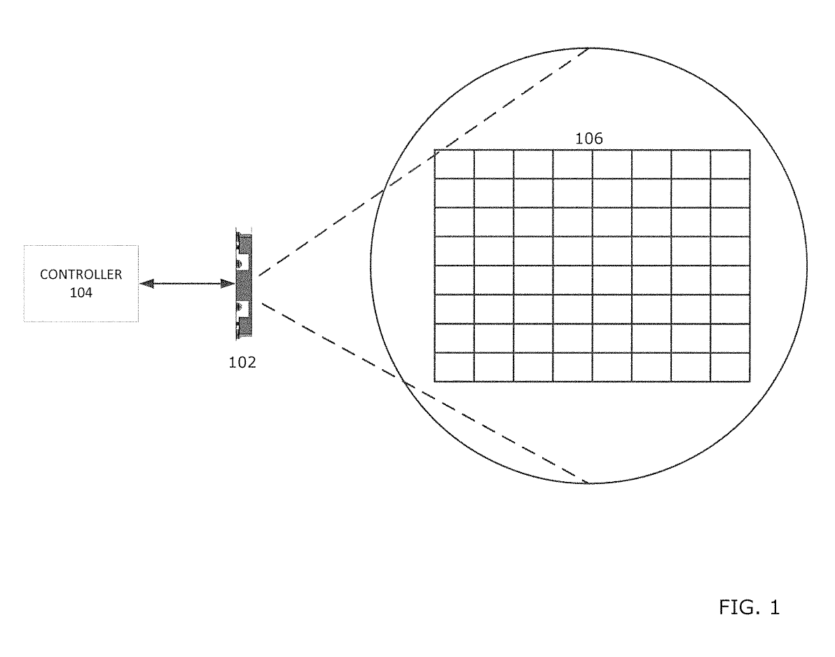

FIG. 1 shows an example of electronic device 102 which is an infrared light emitting diode (IRLED) array controlled by controller 104 (e.g. CPU) to project pixelated IR image 106. IRLED arrays may be used in certain applications (e.g. military applications). For example, missile guidance systems may include IR cameras to track the heat generated by their targets (e.g. enemy planes, vehicles, etc.). In order to assure accuracy, it is beneficial to train these missile guidance systems by projecting a pixelated image onto the IR camera, where the image is then captured an analysed. Thus, the IRLED array can be used to generate a heat signature of the target for the simulation.

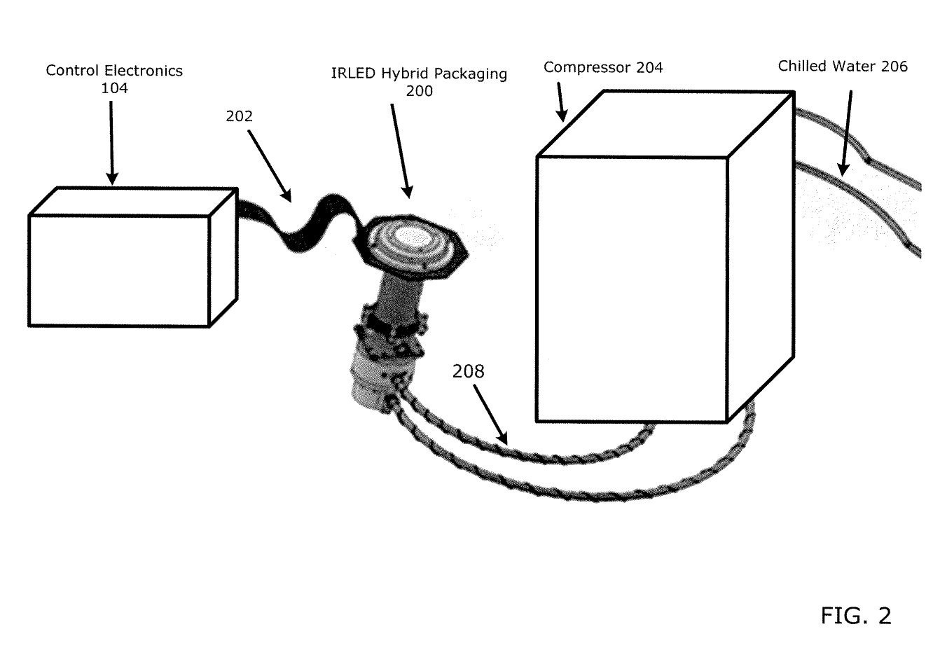

During operation, the temperature of the IRLED increases, thereby emitting heat in the form of waste (e.g. radiated heat separate from the heat signature). To ensure that it operates correctly, the IRLED array must be sufficiently cooled to remove this waste heat. One such solution is to install the IRLED array in a vacuum sealed dewar of a modular dewar system that is designed cool the IRLED array during operation (e.g. extract the waste heat). One example of such a modular dewar system is shown in FIG. 2.

FIG. 2 shows a modular dewar system for cooling the IRLED array in FIG. 1 to maintain an appropriate operating temperature during the simulation. The modular dewar system in FIG. 2 includes a cryo-packaging device 200 (e.g. vacuum sealed dewar and heat exchanger) for vacuum sealing and cooling the IRLED array, control electronics 104 for controlling the IRLED array, and a cooling system 204 including a compressor (not shown), refrigerant lines 208 and chilled water lines 206 for extracting heat from the heat exchanger.

Prior to operation, the IRLED array is mounted and vacuum sealed inside a vacuum chamber of modular dewar 200. However, the electrical connections to the IRLED array remain outside of the vacuum chamber, and are therefore easily accessible by the user. In general, this is accomplished by installing the IRLED array in the center of a printed wiring board (e.g. FR4 PCB) where electrical traces internal to the circuit board electrically connect the IRLED to external connectors (e.g. pins) installed on the outer periphery of the circuit board. By making the circuit board larger than the geometry of the modular dewar, the IRLED array can be sealed within the modular dewar, while its electrical connections can remain outside of the modular dewar. Further details of this feature are described in later figures.

Prior to operation, controller 102 for controlling the IRLED array is connected via cable 202 (e.g. ribbon cable) to the electrical connections of the IRLED array on the outer periphery of the circuit board. Refrigerant lines 208 connect a compressor of cooling system 204 to a heat exchanger of the modular dewar 200.

During operation, as the IRLED array is being controlled by controller 104 to project an IR image through a window of the modular dewar, the system attempts to extract the heat generated by the IRLED array, thereby controlling its operating temperature. This is accomplished by maintaining a vacuum inside the modular dewar and injecting, via the source line of lines 208, refrigerant into a heat exchanger that is thermally coupled to the IRLED array through a cold head. The refrigerant may be a liquid (e.g. R410A) or a gas (e.g. helium).

If the refrigerant is liquid, the heat accepted by the heat exchanger through the cold head extracts the heat by allowing the heat to evaporate the liquid refrigerant turning it into its gas phase. The evaporated refrigerant travels through the return line of lines 208, is further compressed, and then pumped through a condenser where it is cooled back to a liquid state and then eventually pumped back into the heat exchanger for a further cooling cycle. This is a closed system for controlling the temperature of the IRLED array.

If the refrigerant is a gas, the heat accepted by the heat exchanger through the cold head extracts the heat by allowing the gas to absorb the heat and expand. The expanded gas travels through the return line of lines 208 and is cooled. The cooled gas is eventually pumped back into the heat exchanger for a further cooling cycle. This is a closed system for controlling the temperature of the IRLED array. Such systems are well known in the art and need no further explanation.

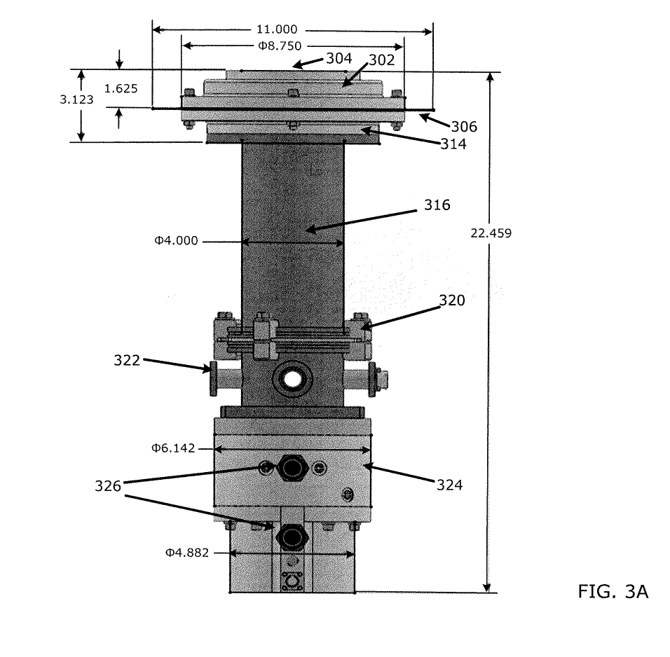

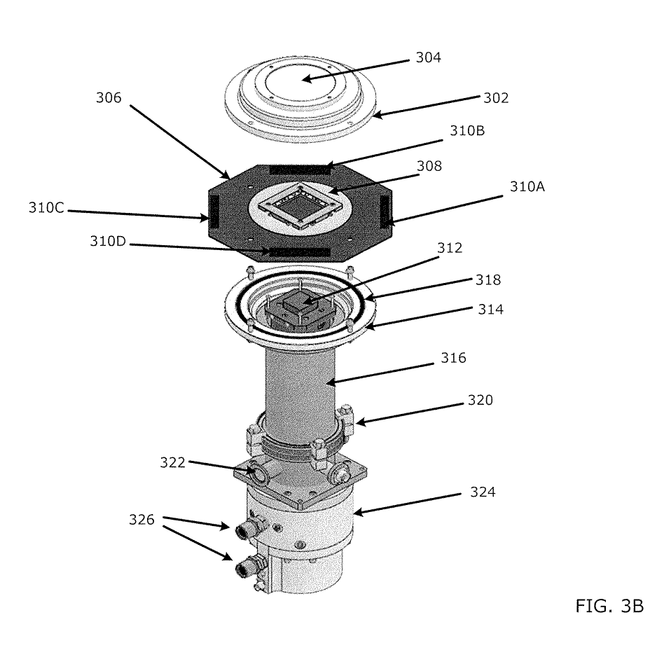

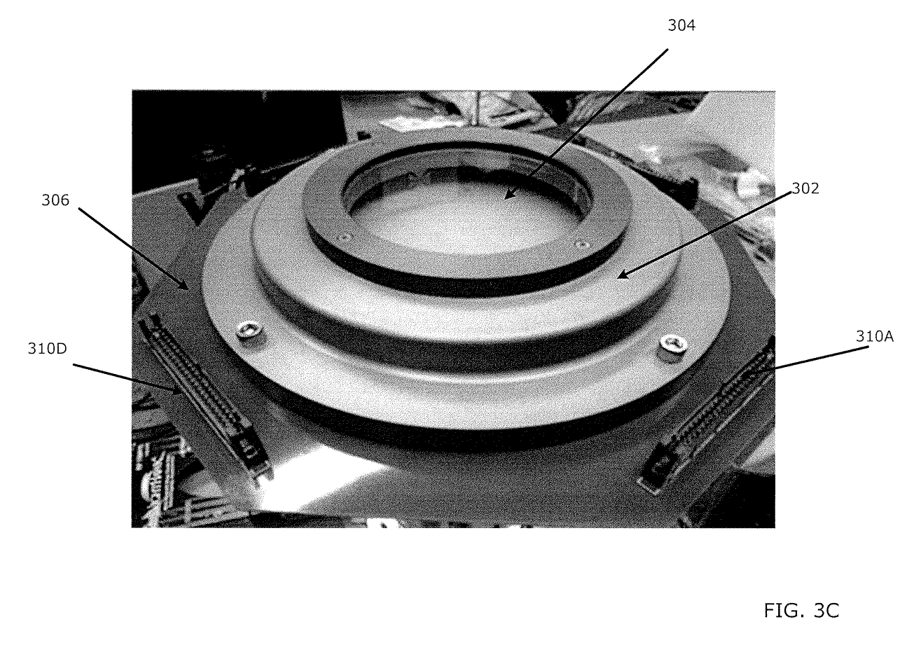

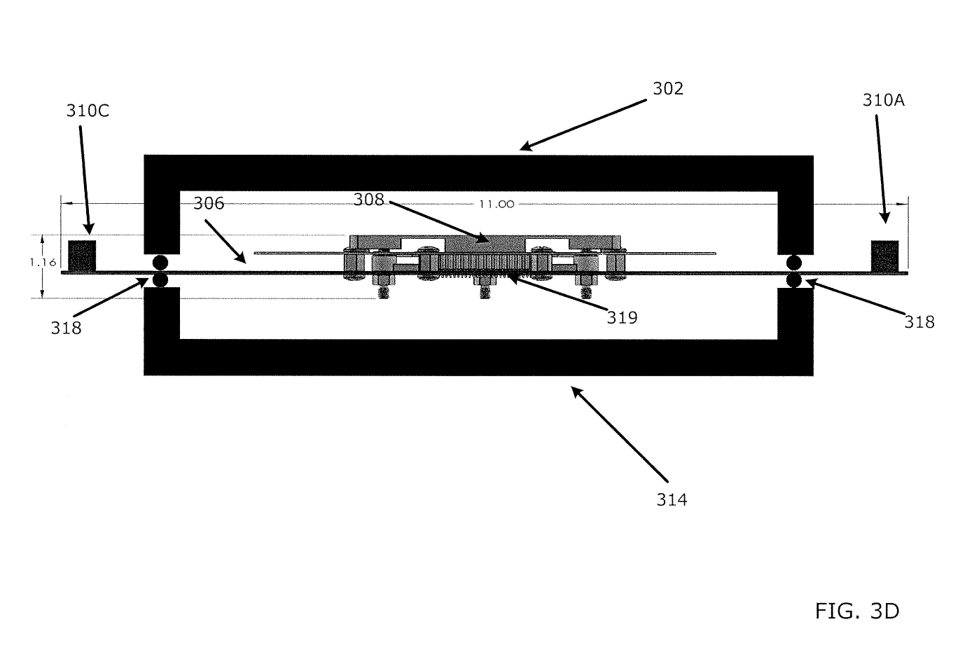

A side view of an exemplary modular dewar 200 is shown in FIG. 3A. Dimensions shown relate to an exemplary embodiment, but the invention is not limited to any particular dimensions of dewar or its component parts. This side view shows that modular dewar 200 includes vacuum chamber 316 having window 304, lid 302, base 314 and vacuum port 322. Also included is heat exchanger 324 having refrigerant ports 326. The heat exchanger is mechanically connected to vacuum chamber 316 via fasteners 320. It should be noted that the dimensions shown in FIG. 3D are just one example of dimensions and geometry for a modular dewar. Other sizes, shapes and overall configurations are possible as long as the IRLED 308 on circuit board 306 can be vacuum sealed, while the electrical connections can be accessed outside of the vacuum seal.

FIG. 3B shows an exploded view of modular dewar 200 in FIG. 3A. In this example, modular dewar 200 has two primary parts including vacuum chamber 316 and heat exchanger 324 which are secured together with fasteners 320 (e.g. screws, bolts, etc.). Vacuum chamber 316 and heat exchanger 324 are thermally coupled to one another via cold head 312 which runs axially through the inside of vacuum chamber 316 and into the heat exchanger 324. Vacuum chamber 316 is comprised of two parts including a base portion 314 having a bottom seal 318 and vacuum ports 322 for connection to a vacuum generator, and a lid portion 302 having a top seal 302 (not shown) and window 304 for allowing the IR image to be projected. Heat exchanger 324 may include internal fins (not shown) for extracting the heat from the modular dewar, and refrigerant ports 326 for connection to the cooling device 204.

Also included is circuit board 306 (e.g. PCB board) including an electronic device (e.g. IRLED array) mounted thereon, and one or more electrical connectors (e.g. pins) 310A-310D that are electrically connected to the IRLED array via traces (not shown) internal to circuit board 306. In general, circuit board 306 is manufactured to have predetermined geometry that positions IRLED array 308 inside of the vacuum chamber of modular dewar 200, while positioning electrical connections 310A-310D outside the vacuum chamber.

In a first configuration, IRLED array 308 and electrical connections 310A-310D are integral to circuit board 306. For example, IRLED array 308 and electrical connections 310A-310D are mounted (e.g. soldered) directly on the traces of circuit board 306 during manufacturing. In second configuration, IRLED array 308 and electrical connections 310A-310D are mounted on separate boards. For example, IRLED array 308 is manufactured on a small IRLED array board, while a separate and larger interposer board having a predetermined geometry is manufactured to have electrical connections 310A-310D and internal traces. The IRLED array board and the interposer board in this second configuration are then physically connected to each other (e.g. IRLED array board is mounted on the interposer board), and the IRLED array is electrically connected (e.g. IRLED array pins are soldered, wire bonded, or plugged into using a socket) to the traces in the interposer board, thereby electrically connecting the IRLED array with the electrical connections. This second configuration may be beneficial when installing pre-existing IRLED arrays into modular dewar 200.

The predetermined geometry of circuit board 306 may be designed based on the geometry of the vacuum chamber. For example, lid 302 and base 314 form a vacuum chamber having a specific size (e.g. diameter and volume). The predetermined geometry of circuit board 306 is designed such that the IRLED array is positioned inside the geometry of the vacuum chamber, while the electrical connections are positioned outside the geometry of the vacuum chamber. For example, the IRLED array would be mounted inside the known perimeter/volume of the vacuum chamber (e.g. inside the perimeter of seals 302/318), while the electrical connections would be mounted outside the known perimeter/volume of the vacuum chamber (e.g. outside the perimeter of seals 302/318).

During installation, board 306 including IRLED array 308 are positioned over base portion 318 of the modular dewar. The backside of IRLED array 308, or a metal plate (not shown) thermally coupled to the back of the IRLED array 308 is positioned to come into physical contact with cold head 312. IRLED array 308 may optionally be screwed to the cold head to ensure this physical contact. Once seated on cold head 312, lid 302 of the modular dewar is positioned over the board such that fastener holes in lid 302, fastener holes in board 306 and fastener holes in base 314 line up. Once the holes are aligned, fasteners (e.g. bolts, screws, etc.) are passed through the holes to sandwich board 306 in between lid 302 and base 314. These fasteners are tightened to compress top seal (e.g. o-ring) 302 against the top surface of board 306, and compress bottom seal 318 (e.g. o-ring) against the bottom surface of board 306 with enough force to create a vacuum seal in the chamber of the modular dewar. Thus, the respective areas of the circuit board that contact the top seal and the bottom seal must be suitably smooth to hold a vacuum seal. In some embodiments, the respective areas may be polished and/or may have an applied coating to make the respective areas relatively smoother than surrounding areas of the circuit board for facilitating the seal, such as a coating of an elastomer, PTFE, a plastic, or the like. In other embodiments, the entire circuit board may be constructed or coated with a material that provides a suitable level of smoothness to maintain a desired vacuum and leakage rate. Surprisingly, it was found that sandwiching the electrical board (e.g. PCB) between lid 302 and base 314 resulted in physical contact between the o-rings and the electrical board surface that was sufficient to maintain a desired vacuum and leakage rate within the dewar. Although depicted with fasteners that extend through the base portion 318 through board 306 and through lid 302, the invention is not limited to any particular structure for generating the compressive force required to sandwich and position the board between the respective seals in the base and lid. Thus, any number of structures may be employed, including “quick connect” configurations that enable faster assembly than a traditional nut and bolt assembly. In a configuration comprising fasteners extending through the base portion 318 through board 306 and through lid 302, the fasteners are configured to receive a tensile force equal to the compressive force required to sandwich the components together to maintain the vacuum seal.

Although not shown, the o-rings may be replaced with other types of seals. For example, indium wire, metal crush gaskets or solder joints may be used to create the vacuum seal. These types of seals may be beneficial in higher vacuum applications that may not be suitable for use of o-rings.

After the board is installed, electrical cables (not shown) are connected to one of more of electrical connections 310A-310D such that IRLED array is connected to other electronic devices (e.g. power sources, controllers, etc.). In addition, a vacuum hose is attached to vacuum port 322 and refrigerant lines are attached to refrigerant ports 326.

Once installation is complete, the system may begin operation. During operation (when IRLED array is operational and producing heat), a compressor attached to port 322 generates and maintains a vacuum in chamber 316, and a compressor attached to ports 326 pumps refrigerant through heat exchanger 324. Heat exchanger is thermally coupled to cold head 312 which is thermally coupled to IRLED array 308. By “thermally coupled” it is meant that the various components are disposed in a relationship with one another that facilitates heat transfer among the components, such as through contact between thermally conductive portions of the respective components in series, as optimized using materials of construction and interfaces known in the field of cryogenics. Thus, IRLED array 308 is thermally coupled to heat exchanger 324 by cold head 312. Thus, heat produced by IRLED array 308 is conducted through cold head 312 and into heat exchanger 324 where it is then extracted by the refrigerant.

A zoomed-in view of the top of modular dewar 200 in FIG. 3A is shown in FIG. 3C, where lid 302 having window 304 is mounted to the base (not shown) of the modular dewar such that circuit board 306 is sandwiched in between. IRLED (not shown) is vacuum sealed in the modular dewar and electrically connected to the external electrical connection pins 310A and 310D which allow for easy connection to other electronic devices such as the IRLED controller.

A cross-sectional view of the top of the modular dewar 200 in FIGS. 3A and 3B is shown in FIG. 3D, where board 306 is shown to be sandwiched between modular dewar lid 302 and modular dewar base 312. A vacuum seal is produced by compressing seals (e.g. o-rings) 318 against the surface of board 306. Thus, an inner portion of board 306 that includes IRLED array 308 is vacuum sealed between lid 302 and base 314, whereas an outer portion of board 306 including electrical connectors 310A and 310C are not vacuum sealed between lid 302 and base 314. In this example, board 306 is implemented as an interposer board, where the smaller IRLED board is mounted on board 306 and electrically connected to the traces of board 306 via connections 319. The electrical traces are not shown, because they run internal to board 306 to connect the IRLED connections 319 to the external electrical connectors 310A and 310C.

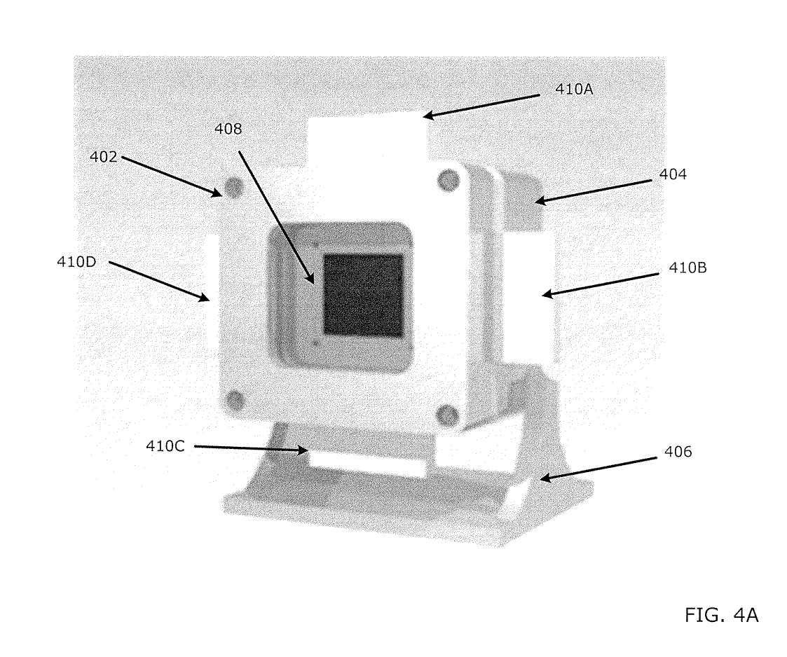

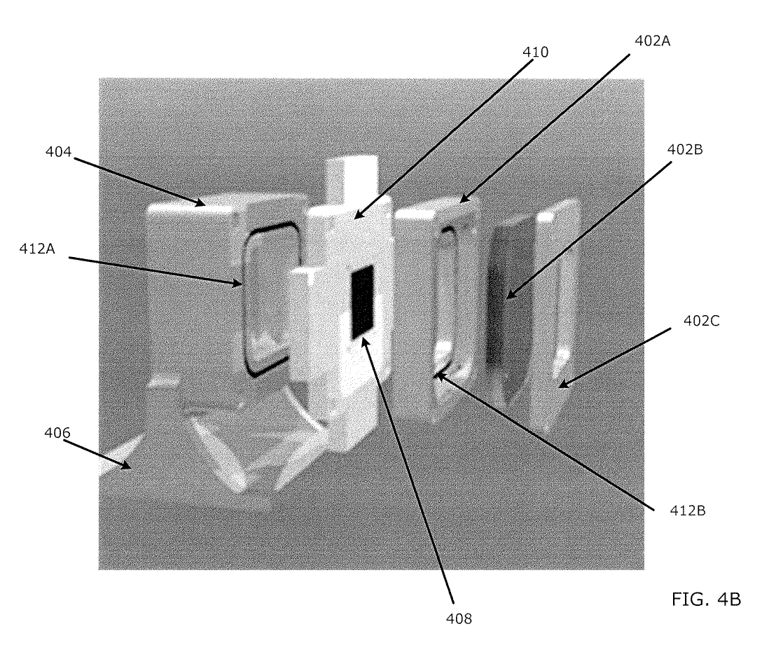

FIG. 4A shows another example of a more compact modular dewar. In this example, the modular dewar includes a vacuum chamber comprised of base part 404 and lid part 402 having a window 408. Circuit board 410 having the IRLED array is sandwiched between lid part 402 and base part 404 such that portions 410A-410D of the circuit board 410 are positioned outside of the vacuum chamber. Although not shown, the electrical connectors are positioned on one or more of portions 410A-410D.

An exploded view of the modular dewar in FIG. 4A is shown in FIG. 4B. As shown, lid 402 may be comprised of multiple parts including lid part 402A and lid part 402C. The window may be a piece of glass 402B that is sandwiched between lid parts 402A and 402C with seal 412B to ensure the vacuum seal integrity. Parts 404, 410, 402A and 402C all have holes to accept fasteners. To install board 410, fasteners are inserted through the aligned holes of parts 404, 410, 402A and 402C, such that window is compressed against seal 412B and circuit board 410 is compressed against bottom seal 412A and a top seal (not shown) on the back of part 402A, although, as noted above, the invention is not limited to the use of threaded fasteners inserted through holes in the subject parts for deriving the requisite compressive force. In addition, mounting base 406 may also be provided for standing modular dewar upright during operation. Mounting base 406 may also be connected to base part 404 via a hinge (not shown) so that the IRLED can be angled during operation.

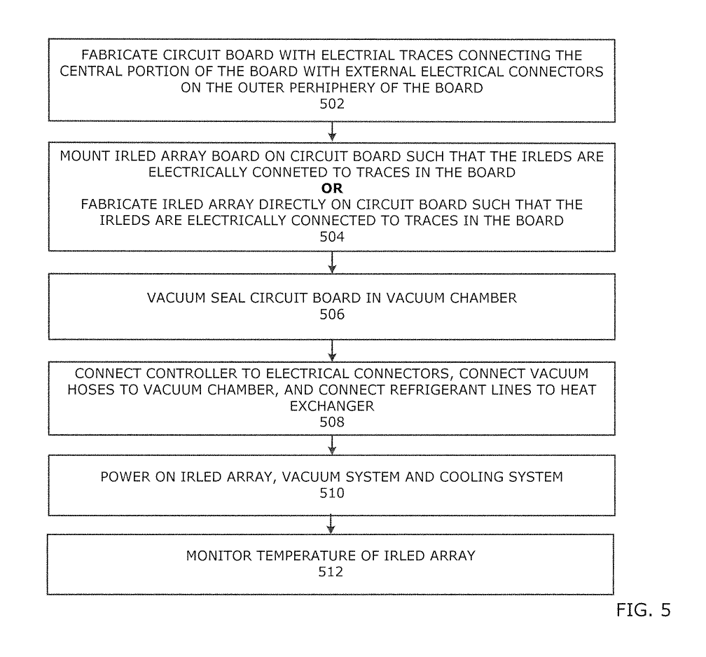

An example of the operation of modular dewar system is described in the flowchart of FIG. 5. In step 502, a circuit board having a predetermined geometry is fabricated. This circuit board includes electrical traces connecting a central portion of the board to electrical connectors mounted on the periphery of the board. In step 504, the IRLED array can either be fabricated on the circuit board or mounted to the circuit board at a later time. In either scenario, the IRLED array is electrically connected to the traces of the circuit board. In step 506, the circuit board is mounted in the vacuum chamber of the modular dewar such that the IRLED array is vacuum sealed in the chamber and the electrical connectors are positioned outside of the chamber. In step 508, the controller for controlling the IRLED array is connected to the electrical connectors, the vacuum pump is connected to the vacuum port via a hose, and the coolant system is connected to the refrigerant ports via hoses. Once the connections are made, in step 510, the system including the IRLED array, vacuum pump and cooling system are powered ON. During operation of the IRLED array, the temperature is monitored via a temperature sensor (not shown). This temperature may be used to control the ON/OFF cycle of the cooling system.

Although the figures and description show and describe the cooling of an IRLED array, it should be noted that any electronic device that generates heat may be cryo-packaged and cooled in the modular dewar. For example, power electronics that generate heat may be cryo-packaged and cooled in the modular dewar in a similar manner. It should also be noted that rather than cooling the electronic components, the modular dewar system may be used to heat the components. For example, if the electronics are to be installed in an extreme cold climate location, the heat exchanger and cooling system of the cryo-packaging system can be redesigned to provide heat to the vacuum sealed electronic device (e.g. hot liquid is pumped through the heat exchanger). This protects the electronic device from the extreme cold ambient temperatures at the installation location. It should also be noted that the modular dewar system may not include a heat exchanger. The modular dewar system may comprise a vacuum chamber used to isolate the components from the ambient environment without providing additional cooling/heating. This may be useful in applications where electronic components may require isolation from contaminants and extreme ambient temperatures.

The method/system for vacuum sealing electronic components avoids the structural limitations of conventional dewars that have a fixed number of ceramic or glass electrical feedthroughs and electrical plug-ins for routing electrical wires and accessing the electrical connections to the chip under test. These feedthroughs are installed during manufacturing and take up valuable space which increases the overall size of the dewar. The number of electrical connections to the electronic device are also limited by the number of feedthroughs provided. In contrast, the present invention allows chips and their PCBs to be installed in the dewar without using the electrical feedthroughs. Therefore, in the present invention, the technician can swap out chips under test and their PCBs without being limited to the fixed number of electrical plug-ins related to the dewar construction.

Although the invention is illustrated and described herein with reference to specific embodiments, the invention is not intended to be limited to the details shown. Rather various modifications may be made in the details within the scope and range of equivalence of the claims and without departing from the invention.

1. A modular dewar comprising:
a vacuum chamber; and
a dewar circuit board including:
an inner portion including an electronic device positioned inside the vacuum chamber,
an outer portion including electrical connectors positioned outside the vacuum chamber, and
electrical traces connecting the electronic device inside the vacuum chamber to the electrical connectors outside the vacuum chamber.

2. The modular dewar of claim 1, further comprising:
a base portion and a lid portion that define the vacuum chamber
a first seal interposed between the base portion and a first face of the dewar circuit board;
a second seal interposed between the lid portion and a second face of the dewar circuit board,
wherein the first seal and the second seal define a vacuum seal between the inner portion of the dewar circuit board and the outer portion of the dewar circuit board.

3. The modular dewar of claim 2,
wherein the first seal and the second seal are o-rings.

4. The modular dewar of claim 2, wherein the base portion, the first seal, the dewar circuit board, the second seal and the lid portion are secured in a compressive relationship with one another by a compressive force.

5. The modular dewar of claim 2, further comprising:
fasteners that pass through the lid portion, the dewar circuit board and the base portion to generate the compressive force.

6. The modular dewar of claim 1, further comprising:
a heat exchanger thermally coupled to the electronic device and configured to extract heat from the electronic device; and
a cold head thermally coupled to the electronic device and the heat exchanger and configured to transfer the heat from the electronic device to the heat exchanger.

7. The modular dewar of claim 1, further comprising:
a heat exchanger thermally coupled to the electronic device and configured to extract heat from the electronic device,
wherein the heat exchanger is a component in a vapor-compression refrigeration system having input and output ports connecting the heat exchanger to a compressor via refrigerant lines.

8. The modular dewar of claim 1,
wherein the electronic device is embedded in the dewar circuit board.

9. The modular dewar of claim 1,
wherein the electronic device is embedded in a carrier circuit board that is electrically connected to the dewar circuit board.

10. The modular dewar of claim 1,
wherein the electronic device comprises an infrared light emitting diode (IRLED) array.

11. A circuit board for cryo-packaging, the circuit board comprising:
an inner portion including an electronic device, the inner portion having a first predetermined geometry for positioning inside a vacuum chamber;
an outer portion including electrical connectors, the outer portion having a second predetermined geometry for positioning outside the vacuum chamber with the inner portion positioned inside a vacuum chamber; and
electrical traces connecting the electronic device to the electrical connectors.

12. The circuit board for cryo-packaging of claim 11, further comprising:
a top surface having an area configured to contact a first seal of the vacuum chamber; and
a bottom surface having an area configured to contact a second seal of the vacuum chamber,
wherein the respective areas of the top surface and the bottom surface are configured to be held in contact with the first and second seal by compressive force suitable to vacuum seal the inner portion of the circuit board inside the vacuum chamber.

13. The circuit board for cryo-packaging of claim 12,
wherein the top surface area and bottom surface area configured to contact the first seal and second seal are constructed to retain vacuum.

14. The circuit board for cryo-packaging of claim 11,
wherein the electrical traces are positioned internal to the circuit board.

15. The circuit board for cryo-packaging of claim 12, further comprising:
fasteners locations on the outer portion of the circuit board for receiving fasteners for bearing a tensile force equal to the compressive force for holding the first seal and second seal in contact with the circuit board.

16. The circuit board for cryo-packaging of claim 11,
wherein the electrical connectors are pin connectors.

17. The circuit board for cryo-packaging of claim 11, further comprising:
a thermal contact surface positioned below the electronic device to thermally couple the electronic device to a heat exchanger.

18. The circuit board for cryo-packaging of claim 11,
wherein the electronic device is embedded in the circuit board.

19. The circuit board for cryo-packaging of claim 11,
wherein the circuit board is a first circuit board and the electronic device comprises a separate, second circuit board electrically connected to the first circuit board.

20. The circuit board for cryo-packaging of claim 11,
wherein the electronic device comprises an infrared light emitting diode (IRLED) array.

21. A modular dewar comprising:
a vacuum chamber defined by a front lid and a rear lid;
an interposer comprising an electrically insulating substrate having a first face in contact with a first vacuum seal in contact with the front lid and a second face in contact with a second vacuum seal in contact with the rear lid, the interposer comprising:
an inner portion positioned inside the vacuum chamber and containing a first electronic component,
an outer portion positioned outside the vacuum chamber and containing one or more second electronic components, and
electrically conductive layers or members; and
a temperature regulation device configured to cool the dewar,
wherein the modular dewar is configured to permit exchanging the first electronic component for a second electronic component different than the first electronic component without requiring modifications to the modular dewar.
